(19) United States
(12) Patent Application Publication
(10) Pub. No.: US 2026/0239989 A1
(43) Pub. Date: Aug. 13, 2026

(54) METHODS AND APPARATUS FOR PACKAGE LEVEL HYBRID ELECTROMAGNETIC INTERFERENCE SHIELDS

(71) Applicant: Intel Corporation, Santa Clara, CA (US)

(72) Inventors: Dong-Ho Han, Beaverton, OR (US); Alonso Rodriguez Chacon, Guacima (CR); Quek Liang Wee, Bayan Lepas (MY); Jerrod Peterson, Hillsboro, OR (US); Jose Diaz, San Jose (CR); Bernardo Mora Villalobos, Alajuela (CR); Bala Subramanya, Bangalore (IN); Boon Ping KOH, Seberang Jaya (MY); Jun He, Shanghai (CN)

(21) Appl. No.: 19/074,168

(22) Filed: Mar. 7, 2025

(30) Foreign Application Priority Data
Feb. 13, 2025 (WO) PCT/CN2025/077103

(51) Int. Cl. H01L 23/552; H01L 21/50; H01L 23/10; H01L 23/367; H10B 80/00

(52) U.S. Cl. CPC H10W 42/20; H10W 76/60; H10W 95/00; H10B 80/00; H10W 40/22

(57) ABSTRACT

Methods and apparatus for package level hybrid electromagnetic interference (EMI) shields are disclosed. A disclosed example shield for a die package includes a first shield portion defining a first section of a perimeter of the EMI shield, the first shield portion including a first EMI absorbing material with a first characteristic, and a second shield portion defining a second section of the perimeter, the second shield portion including a second EMI absorbing material with a second characteristic different from the first characteristic, the first and second shield portions to be electrically coupled to a ground plane of the die package when the EMI shield is coupled to the die package.

### RELATED APPLICATION

This patent arises from International Application No. PCT/CN2025/077103, which was filed on Feb. 13, 2025. International Application No. PCT/CN2025/077103 is hereby incorporated herein by reference in its entirety. Priority to International Application No. PCT/CN2025/077103 is hereby claimed.

### FIELD OF THE DISCLOSURE

This disclosure relates generally to die packages and, more particularly, to methods and apparatus for package level hybrid electromagnetic interference shields.

### BACKGROUND

Memory bandwidth-intensive artificial intelligence (AI) system on chip (SoC) systems access multi-channel double data rate (DDR) dynamic random access memory (DRAM) devices or a relatively large number of DRAM data lanes that utilize single-ended signaling. When a typical mobile computing heat solution is utilized with such an AI SoC, digital noise corresponding to the aforementioned DRAM devices can be coupled to a cold plate and a heat pipe of the heat solution, thereby resulting in significant electromagnetic interference (EMI) and/or radio frequency interference (RFI). Accordingly, EMI shields are implemented to isolate DRAM radiation from Wi-Fi and cellular antennas.

### BRIEF DESCRIPTION OF THE DRAWINGS

FIG. 1 depicts an example package in which examples disclosed herein can be implemented.

FIG. 2 is a cross-sectional view of another example package in which examples disclosed herein can be implemented.

FIGS. 3A and 3B depict an example platform in which examples disclosed herein can be implemented.

FIG. 4 depicts example electromagnetic interference (EMI) shield implementations in accordance with teachings of this disclosure.

FIG. 5 depicts example alternative EMI shield implementations in accordance with teachings of this disclosure.

FIGS. 6A-6F depict example shield portion configurations that can be implemented in examples disclosed herein.

FIG. 7 is a cross-sectional view of an example utilization of a stiffener adhesive that can be implemented in examples disclosed herein.

FIG. 8 is a flowchart representative of an example method to produce examples disclosed herein.

FIG. 9 is a graph depicting example results that can be achieved with examples disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Methods and apparatus for package level hybrid electromagnetic interference (EMI) shields are disclosed. Known systems utilize on-board EMI shields to enclose a system on chip (SoC) package having dynamic random access memory (DRAM) devices. Such known systems can cause a reduction in usable printed circuit board (PCB) area due to the DRAM devices and, thus, can necessitate significant PCB area and system Z-height corresponding to EMI fences. Further, known systems utilize relatively complex multi-height lids that can be costly to produce.

Examples disclosed herein enable compact and space-saving packages, which can be highly advantageous for platforms and/or SoCs. Examples disclosed herein can increase available space on a substrate and/or PCB of a die package. Examples disclosed herein can enable effective EMI shielding of a package that includes and/or supports a processor die (e.g., a chiplet, etc.) in combination with a memory die, such as an on-board memory device (e.g., DRAMs).

Examples disclosed herein implement a hybrid shielding solution that can be highly advantageous in devices (e.g., computing devices, mobile devices, phones, tablets, etc.) that utilize semiconductor packages, such as die packages, memory packages, SoC packages, etc. Examples disclosed herein divide an EMI shield into multiple shield portions (e.g., shield wall portions) with different EMI characteristics, EMI absorbing/shielding materials and/or implementations. For example, a first shield portion can correspond to a first type of EMI implementation and the second shield portion can correspond to a second type of EMI implementation different from the first type. In turn, the aforementioned shield portions can be grounded to a ground plane of a printed circuit board (PCB) or substrate of the package, thereby enabling a compact and highly integrated EMI solution. As a result, examples disclosed herein can enable significantly more compact package implementations. Further, examples disclosed herein can enable flexibility in terms of routing, component selection and component placement.

In some examples, at least one of the shield portions includes segments with a gap therebetween. Additionally or alternatively, at least one of the shield portions includes a compressible gasket to be placed against a component mounted to the PCB of the package. In some examples, at least one of the shield portions includes a board mounted EMI gasket or device. In some examples, the package includes at least one of a processor die and/or a chiplet (e.g., an SoC chiplet) in combination with a memory die and/or device (e.g., a DRAM component).

As used herein, the term “characteristic” with respect to EMI material, EMI shielding and EMI absorbing material refers to characteristics, properties and/or structures that effect EMI absorption. Accordingly, in such a context, the term “characteristic” being different can refer to different implementation types, different materials, different structures and/or different types, etc.

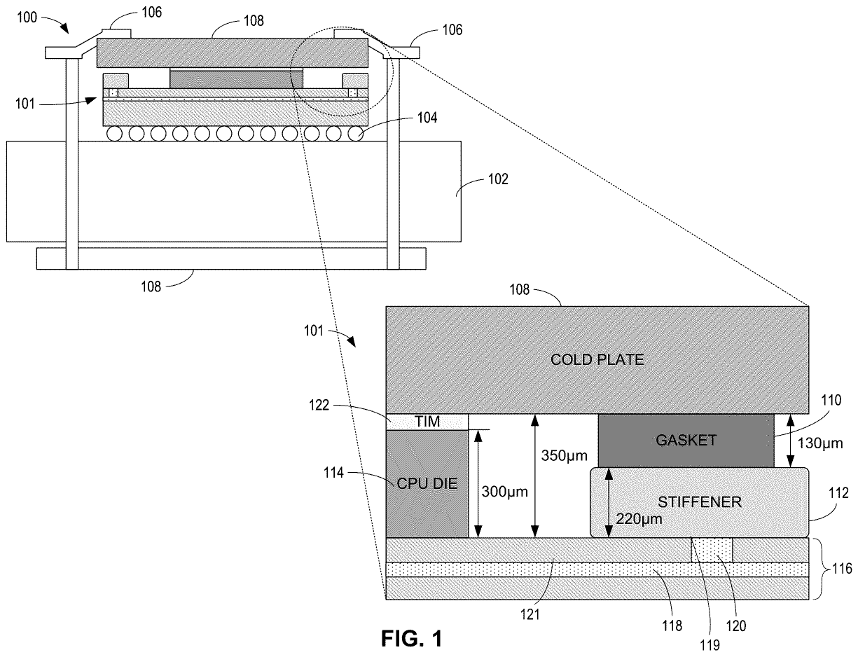

FIG. 1 depicts a portion of an example computing device (e.g., a laptop, a tablet, a mobile device, a mobile phone, etc.) 100 having an example package (e.g., a chip package, a die package, a processor package, a computing device package, a memory on package, a die-memory package, etc.) 101 in which examples disclosed herein can be implemented. In the illustrated view of FIG. 1, the example package 101 is implemented as an SoC package. The example package 101 is mounted on a substrate (e.g., a circuit board, a motherboard, etc.) 102 via a ball grid array (BGA) 104. Further, braces 106 are implemented to hold and/or position a cold plate (e.g., a cooling plate, a shield lid, a vapor chamber plate, etc.) 108 relative to the package 101. In some examples, the cold plate 108 can be implemented as a vapor chamber. In this example, an EMI gasket (e.g., a compressible EMI gasket) 110 is positioned and/or compressed between the aforementioned cold plate 108 and a stiffener (e.g., a metal stiffener) 112. According to examples disclosed herein, the EMI gasket 110 can be implemented as a conductive elastic material, such as conductive foam or rubber, for example. However, any other appropriate (e.g., compressible) EMI-reducing material can be implemented instead.

In this example, the package 101 includes and/or supports a processor die (e.g., a central processing unit (CPU) die, a graphics processing unit (GPU) die, a processor chip, etc.) 114 mounted to a package substrate (e.g., a circuit board, a PCB, etc.) 116. In turn, the package substrate 116 includes a ground plane 118, conductive epoxy 120 smeared to a solder mask opening 119 for grounding of the stiffener 112 (one of the stiffeners 112 is shown in FIG. 1 for simplicity), and a solder mask 121. In this example, the conductive epoxy 120 electrically couples the ground plane 118 to the stiffener 112. Further, a thermal interface material (TIM) 122, which may be at least partially composed of a compressible material, is positioned and/or placed between the processor die 114 and the cold plate 108 for heat conduction therebetween. In this example, the processor die 114 is approximately 250 microns (μm) to 350 μm (e.g., 300 μm) in thickness, (the distance between the package 103 and the cold plate 108 is approximately 300 μm to 400 μm (e.g., 350 μm) in thickness. Further, the example stiffener 112 is approximately 200 μm to 240 μm (e.g., 220 μm) in thickness. However, any other appropriate dimensions, spacings and/or thicknesses can be implemented instead.

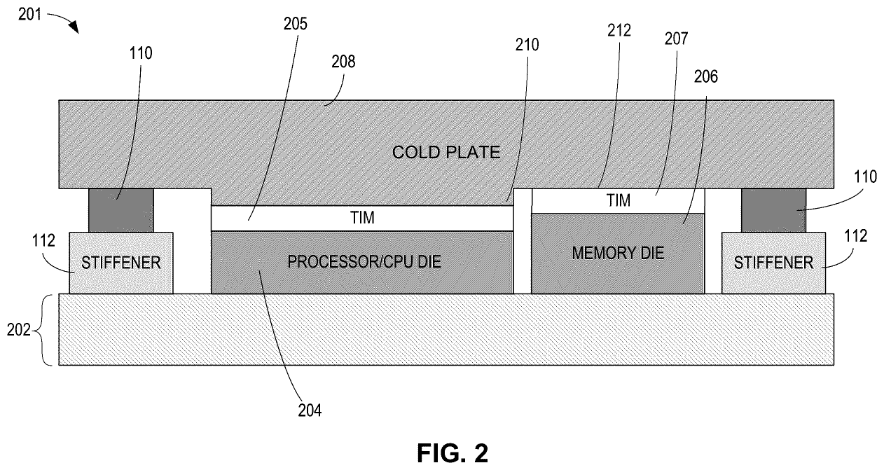

To define a relatively compact EMI shield, as will be discussed below in connection with FIGS. 2-9, examples disclosed herein utilize electrical coupling between the ground plane 118, the conductive epoxy 120, the stiffener 112, the EMI gasket 110 and the cold plate 108. In other words, the ground plane 118, the conductive epoxy 120, the stiffener 112, the EMI gasket 110 and the cold plate 108 act as a PCB-level EMI shield solution, which is highly advantageous from a perspective of compactness. Accordingly, the compactness can enable smaller and more space-efficient electronic and/or computing devices. Examples disclosed further herein utilize multiple shield portions to define a hybrid shielding solution. Particularly, the shield portions have different EMI characteristics (e.g., the shield portions have different types of EMI solutions/types/materials), thereby defining a hybrid EMI solution that can enable further space-saving as well as tailored EMI configurations and/or geometries. In particular, the different EMI characteristics of the shield portions on the same shield enables flexibility for die packages as well as increased compactness. Moreover, examples disclosed herein enable highly effective EMI shielding for hybrid packages, such as packages supporting a die and/or processor along with a memory die and/or a memory device (e.g., DRAM). Further, by grounding EMI shields to cold plates and, in turn, heat pipes, examples disclosed herein do not necessitate EMI gaskets on the heat pipes, as typical in known implementations.

FIG. 2 is a cross-sectional view of an alternative example package 201 in which examples disclosed herein can be implemented. The package 201 is similar to the example package 101 of FIG. 1, and includes a package substrate (e.g., a circuit board, a PCB, etc.) 202 supporting a processor die 204, TIM 205, and, in contrast to the example of FIG. 1, includes memory die 206 with corresponding TIM 207. The package further includes the gasket 110 and the stiffener 112. In this example, a cold plate 208 includes at least one protrusion 210 for contact with the die 204 (e.g., contact with the aforementioned TIM 205 positioned between the processor die 204 and the protrusion(s) 210). Similarly, the TIM 207 is positioned between the memory die 206 and a surface 212 offset (vertically in the view of FIG. 2) from the protrusion 210.

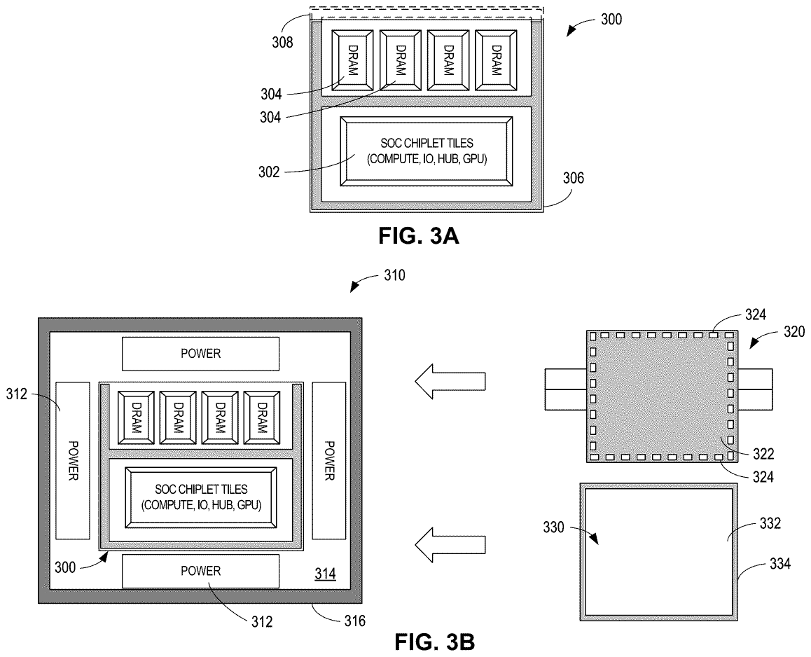

FIGS. 3A and 3B depict an example platform that can implement examples disclosed herein. Turning to FIG. 3A, an overhead view of an example package 300 in which examples disclosed herein can be implemented is shown. In the illustrated example of FIG. 3A, the package 300 is shown having a die (e.g., a chiplet, a chiplet die, an SoC chiplet, a tile, a graphics processing unit (GPU), input output (I/O) (an I/O hub, a data interface hub, etc.) 302, as well as memory (e.g., memory chips, memory devices, etc.) 304, which are implemented as DRAM components in this example. As can be seen in the illustrated example, the die 302 and the memory 304 are generally enclosed (e.g., laterally enclosed or surrounded) by a stiffener (e.g., a fence) 306. In this example, the stiffener 306 is approximately 1-3 millimeters (mm) (e.g., 2 mm) in width. However, any other appropriate width can be implemented instead.

To advantageously reduce a size and/or a footprint of the package 300, examples disclosed herein can utilize hybrid shielding to reduce an amount of stiffener and/or shielding that is typically necessitated for packages. In particular, examples disclosed herein can utilize two or more different shielding types and/or implementations to reduce an overall size and/or an occupied volume of the package 300 by reducing or eliminating space typically necessitated for a stiffener and/or stiffener routing. As a result, examples disclosed herein can also enable increased routing and/or component space, thereby resulting in more compact packages. As can be seen in the example of FIG. 3A, a region 308 corresponds to an area of the package 300 that would ordinarily utilize a stiffener and/or shield and, thus, would necessitate an increased space, as well as prevent routing of traces and/or layers thereon. In contrast, examples disclosed herein can advantageously forego the depicted region 308 to reduce space and volume utilization.

FIG. 3B depicts an example platform 310 implementing the example package 300 shown in FIG. 3A. In this example, the platform 310 supports the package 300 as well as power circuitry (e.g., power delivery chips, power delivery components, etc.) 312 placed at outer edges of the package 300. According to examples disclosed herein, the package 300 and the power circuitry 312 are mounted to and/or supported by a substrate (e.g., a board, a circuit board, a PCB, a board substrate, etc.) 314. Further, in known implementations, an EMI shield lid extends between, across and/or around an EMI perimeter (e.g., an EMI fence) 316, thereby necessitating increased height usage. With respect to these known implementations of the EMI shield spanning across (and beyond) the EMI perimeter 316, the increased height and additional utilized or occupied space of the substrate 314 can increase a size of a device while reducing a potential routing area/volume.

In contrast to the known implementations, examples disclosed herein can span across a reduced area. In other words, examples disclosed do not necessitate spanning across the entirety of the perimeter 316, and can also enable a reduction in height (e.g., z-height reduction along a direction into/out of the page of FIG. 3B) as well as a reduction in lateral space required (e.g., an area that spans horizontally and vertically in the view of FIG. 3B). As a result, examples disclosed herein can significantly reduce occupied volume and/or space to enable more compact packages and, in turn, devices.

In accordance with teachings of this disclosure, examples disclosed herein can utilize shielding and/or structures (e.g., EMI lids, shielding, vapor chambers, cooling blocks, etc.) that are significantly smaller than known implementations. To that end, examples disclosed herein can utilize a package-level EMI shield 320 with a cold plate 322 having contact pads (e.g., printed EMI contact pads) 324 printed and/or applied thereon. In particular, contact pads 324 can be spaced apart on at least a portion of an outer perimeter thereof.

In some other examples, a package-level EMI shield 330 includes a cold plate 332 with a gasket 334 on at least a portion and/or a section of a perimeter of the shield 330. As can be seen in the view of FIG. 3B, the example shield 320 and the example shield 330 have significantly smaller footprints than the perimeter 316, which defines a typical shielding footprint in known implementations.

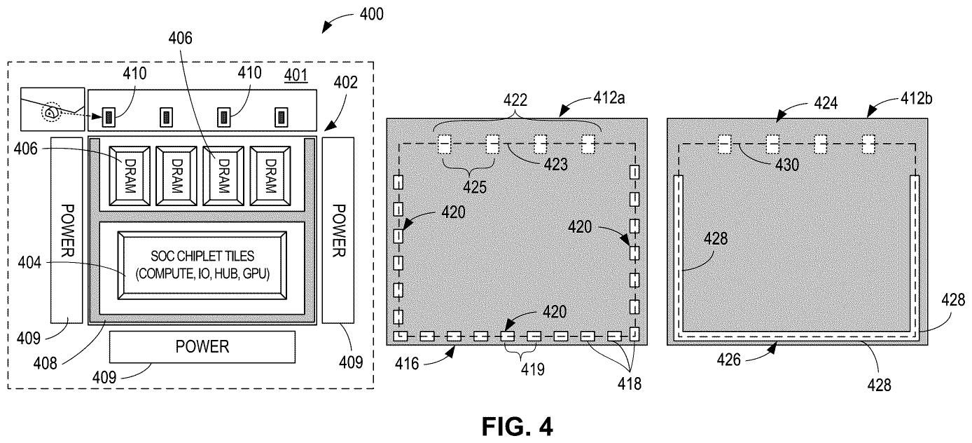

FIG. 4 depicts example electromagnetic interference (EMI) shield implementations in accordance with teachings of this disclosure. According to examples disclosed herein, a platform 400 is shown with a board (e.g., a substrate, a circuit board, a PCB, a motherboard, etc.) 401 supporting a package (e.g., a die package, an SoC package, a hybrid package, a memory package, a processor-memory package, etc.) 402. In turn, the example package 402 includes, supports and/or mounts an SoC chiplet (e.g., an SoC chiplet tile) 404, memory 406, a stiffener 408 and power circuitry (e.g., power delivery chips, power devices, power chips, etc.) 409. In this example, the board 401 has EMI gaskets (e.g., EMI gasket portions, EMI surface mountable gaskets, EMI contacts, board-mounted EMI gaskets, etc.) 410 mounted thereon. In the illustrated view of FIG. 4, example cold plates 412 (hereinafter cold plates 412a, 412b, . . . etc.) are shown in the same view to illustrate alternate example hybrid EMI solutions that can be utilized with the package 402.

To define a hybrid EMI shield that at least partially covers and/or laterally surrounds the SOC chiplet 404 and the memory 406, examples disclosed herein implement distinct shield sections, areas and/or portions with different EMI characteristics (or implementation types) along a perimeter thereof. According to examples disclosed herein, the cold plate 412 is shown with a first shield portion (e.g., a first shield wall portion) 416 defined by segments (e.g., wall elements, spaced apart segments, etc.) 418 that are spaced apart (e.g., evenly spaced apart, unevenly spaced apart). In this example, the first shield portion 416 defines three shield walls 420 of the hybrid EMI shield. However, the first shield portion 416 can define any other appropriate number of the walls (e.g., one, two, four, . . . etc.). In this example, a second shield portion (e.g., a second shield wall portion) 422 is defined by the aforementioned EMI gaskets 410 mounted to the board 401, thereby defining one of the walls of the hybrid EMI shield. Accordingly, the first shield portion 416 and the second shield portion 422 define a perimeter (e.g., an EMI shield perimeter) 423 with different EMI characteristics, implementations, materials, structures and/or types.

In some examples, widths (e.g., lateral widths) of the EMI gaskets 410 are different from (e.g., greater than, less than) widths of the segments 418. In some examples, the first shield portion 416 includes the aforementioned first segments 418 that are separated from one another by a first spacing (e.g., a first pitch) 419 while the second shield portion 422 includes second segments that are separated from one another by a second spacing (e.g., a second pitch) 425 different from the first spacing. The first spacing can be greater or less than the second pitch. In other examples, the first spacing 419 and the second spacing 425 are the same (e.g., within 5% of one another). In some examples, the EMI gaskets 410 are board-mounted via a surface mount technology (SMT) process, for example. In some such examples, the EMI gaskets 410 can be compressible (e.g., against the cold plate 412a).

Alternatively, the example cold plate 412b is shown having a perimeter with a first shield portion 424 defined by the EMI gaskets 410, and a second shield portion 426 defined by walls (e.g., wall portions) 428 that are generally continuous (e.g., coupled to one another at corners). In this example, the first shield portion 424 and the second shield portion 426 define a perimeter 430 with different EMI characteristics, implementations and/or types. While the second shield portion 426 is shown defining three walls of the perimeter, the second shield portion 426 can define any other appropriate number of the walls instead (e.g., one, two, four, . . . etc.).

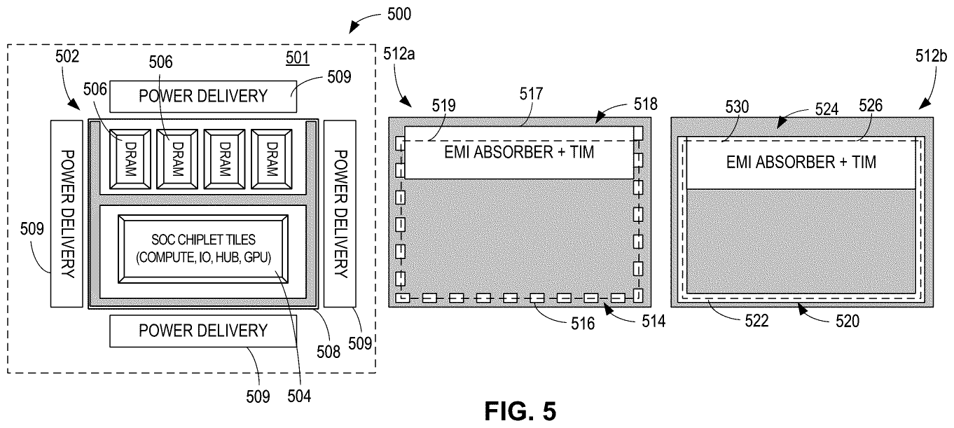

FIG. 5 depicts example alternative EMI shield implementations in accordance with teachings of this disclosure. In the illustrated example of FIG. 5, a platform 500 is shown with a board (e.g., a PCB, a motherboard, a substrate, etc.) 501 supporting a package 502 that supports and/or mounts an SoC chiplet tile 504, memory 506, a stiffener 508 and power circuitry (e.g., power delivery devices, etc.) 509 that laterally surround the memory 506 and the SoC chiplet tile 504. In the illustrated view of FIG. 5, example cold plates 512 (hereinafter cold plates 512a, 512b, . . . etc.) are shown in the same view to illustrate alternate example hybrid EMI solutions.

According to examples disclosed herein, the example cold plate 512a includes a first shield portion 514 defined by segments 516 while a second shield portion 518 is defined by an EMI absorbing material (e.g., a compressible EMI material, an EMI gap filler material, etc.) 517. Accordingly, in this example, the first shield portion 514 and the second shield portion 518 define a perimeter 519. The example segments 516 can be regularly or irregularly spaced (e.g., same or varying spacing therebetween). In some examples, the aforementioned EMI absorbing material 517 is a relatively pliable gap filler material that is at least partially compressed between at least one of the power circuitry 509 as well as the cold plate 512a. In this example, the EMI absorbing material 517 includes a TIM and/or defines a TIM to advantageously cool the memory 506, for example.

In the illustrated example of FIG. 5, the cold plate 512b is shown along with the cold plate 512a. The depicted example corresponding to the cold plate 512b is similar to the example cold plate 512a but, instead, a first shield portion (e.g., a first shield wall portion) 520 is implemented as a relatively continuous wall 522. In the illustrated example of FIG. 5, a second shield portion (e.g., a second shield wall portion) 524 implemented with EMI absorbing material 526. In some examples, the second shield portion 524 extends to contact and/or compressibly interfere with (e.g., the first wall portion at distal ends thereof. In this example, the first shield portion 520 and the second shield portion 524 define a perimeter 530.

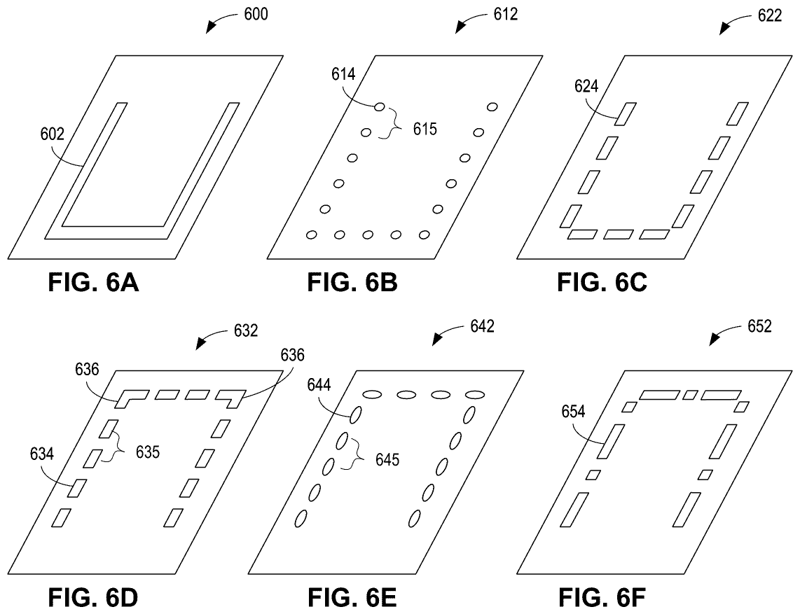

While the examples of FIGS. 4 and 5 depict hybrid EMI shielding that define portions or sections of perimeters based on demarcating edges or sides, examples disclosed herein can also subdivide at least one wall, edge and/or perimeter segment. In other words, the shield portions can be demarcated within walls and/or edges (e.g., two or more shield portions subdivide a wall or an edge). Further, while the examples of FIGS. 4 and 5 (as well as FIGS. 6A-6F below) depict divisions of three walls of a first EMI characteristic in combination with a wall of a second EMI characteristic different from the first characteristic, examples disclosed herein can be implemented with any appropriate wall combination (e.g., two walls of the first EMI characteristic in combination with two walls of the second EMI characteristic, four walls of the first EMI characteristic in combination with two walls of the second EMI characteristic, etc.). Further, examples disclosed herein can have shield perimeters with different shapes (e.g., round, irregular, etc.).

FIGS. 6A-6F depict example implementations of printed and/or applied EMI absorbing material patterns that can be utilized for hybrid shielding in accordance with teachings of this disclosure. Turning to FIG. 6A, an example cold plate 600 is shown with a continuous shield portion 602 of applied and/or dispensed EMI material (e.g., a printed EMI material pattern).

In the illustrated example of FIG. 6B, an example cold plate 612 is shown. The example cold plate 612 includes a shield portion 614 having uniform dots of applied and/or dispensed EMI material spaced apart and/or having a spacing 615 that is relatively uniform.

FIG. 6C depicts an example cold plate 622 having a shield portion 624 which, in turn, includes relatively uniform rectangular segments of EMI material spaced apart and/or having a spacing that is relatively uniform.

In the illustrated example of FIG. 6D, an example cold plate 632 is shown. The example cold plate 632 includes a shield portion 634 that is similar to the shield portion shown in FIG. 6C with the shield portion 634 also including relatively uniform rectangular segments spaced apart and/or having a spacing 635 that is relatively uniform. However, in this example, the shield portion 634 includes corner segments 636.

FIG. 6E depicts an example cold plate 642 with a shield portion 644 including ellipsoid and/or oval segments of EMI material having a relatively uniform spacing 645.

FIG. 6F depicts an example cold plate 652 with a shield portion 654 including irregularly sized and/or width segments of applied and/or dispensed EMI material.

Any of the example aspects of FIGS. 4-6F can be combined with one another. Further, any appropriate number of wall segments and/or edges can be implemented instead. Further, while many of the examples of FIGS. 4-6F depict application of EMI material to a cold plate, examples disclosed herein can be applied to any appropriate component device and/or assembly including, but not limited to, a vapor chamber, a vapor chamber plate, a cooling plate, a shield lid, etc.

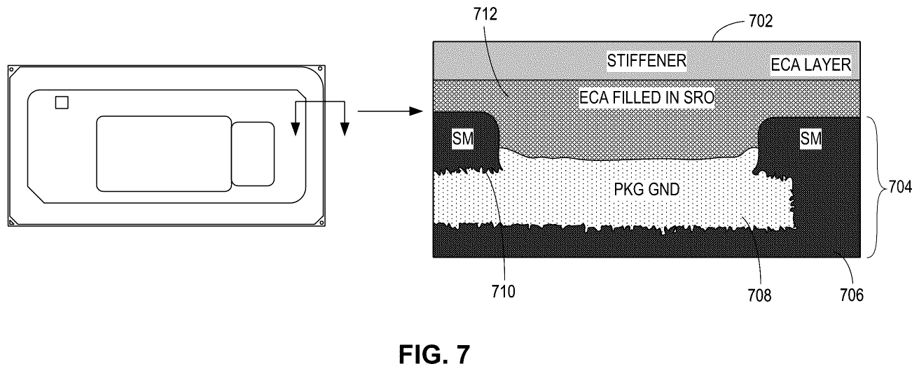

FIG. 7 is a detailed cross-sectional view showing an area between a stiffener 702 and a package 704 which, in turn, includes a substrate 706. In this example, a ground (e.g., a ground pad) 708 is exposed in an opening of a solder mask 710. According to examples disclosed herein, an adhesive (e.g., an adhesive layer) 712 is depicted as being positioned between the stiffener 702 and the ground 708. In particular, the adhesive 712 of the illustrated example is an electrically conductive adhesive (ECA) that can be utilized in relatively low temperature bonding. The aforementioned ECA is commonly referred to as an epoxy. Additionally or alternatively, an insulating adhesive resin can be utilized with silver flakes.

In the illustrated view of FIG. 7, a metal stiffener on a package for mitigating warpage risks (e.g., during PCB solder assembly, etc.) is depicted. However, the stiffener 702 can be a source of crosstalk and/or EMI issues without adequate electrical grounding contacts. In this example, the stiffener 702 has been assembled using the aforementioned ECA). According to some examples disclosed herein, solder mask openings are placed roughly every 2 mm distance along the perimeter of the package for electrical contact to a package ground plane via the ECA, which can be applied by smearing for example. However, any other appropriate distance can be implemented instead.

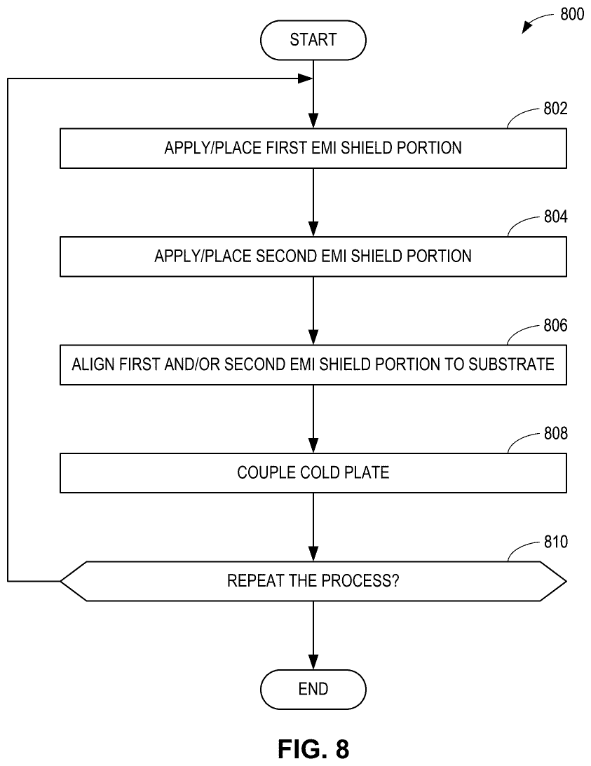

FIG. 8 is a flowchart representative of an example method 800 to produce examples disclosed herein. The example method 800 begins at block 802 as a first EMI shield portion is applied and/or placed onto a device package (e.g., a processor package, a memory on package, an SoC, etc.). According to some examples disclosed herein, the first EMI shield portion is placed, deposited, dispensed and/or printed.

At block 804, a second EMI shield portion is applied and/or placed. In some examples, the second shield portion is defined on a cold plate to contact and/or at least partially interfere with the first EMI shield portion.

At block 806, in some examples, the first EMI shield portion and/or the second EMI shield portion is aligned to a substrate and/or a PCB. According to some examples disclosed herein, a feature (e.g., a tab) of a cold plate carrying at least one of the first or second EMI shield portions is aligned to corresponding feature (e.g., an aperture) of

At block 808, in this example, a cold plate and/or shield lid is coupled to a package and/or a stiffener of the package.

At block 810, it is determined whether to repeat the process. If the process is to be repeated (block 810), control of the process returns to block 802. Otherwise, the process ends. The determination may be based on whether additional hybrid EMI shields are to be defined, produced and/or place.

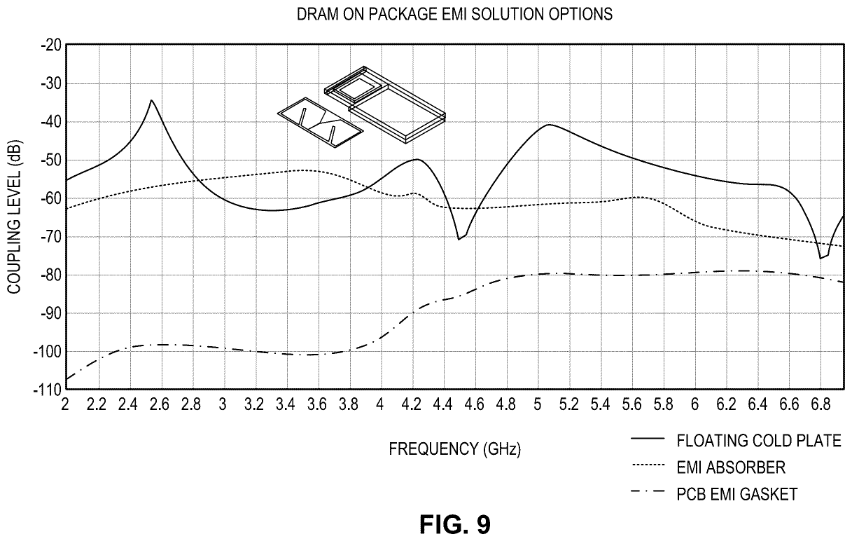

FIG. 9 is an example graph depicting example results that can be achieved with examples disclosed herein. In the illustrated example of FIG. 9, comparisons of Wi-Fi antenna noise coupling levels from 3D full-wave electromagnetic simulations of hybrid (PCB and package) EMI shield solutions are depicted including: (i) EMI absorber gap pad over the DRAM and (ii) the PCB SMT EMI gasket contacts for a cold plate.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example methods, apparatus, systems, and articles of manufacture to enable compact EMI shielding for die packages are disclosed herein. Further examples and combinations thereof include the following:

Example 1 includes an electromagnetic interference (EMI) shield for a die package, the shield comprising a first shield portion defining a first section of a perimeter of the EMI shield, the first shield portion including a first EMI absorbing material with a first characteristic, and a second shield portion defining a second section of the perimeter, the second shield portion including a second EMI absorbing material with a second characteristic different from the first characteristic, the first and second shield portions to be electrically coupled to a ground plane of the die package when the EMI shield is coupled to the die package.

Example 2 includes the shield as defined in example 1, wherein the first EMI absorbing material is a first EMI gasket and the second EMI absorbing material is a second EMI gasket, the first and second EMI gaskets to contact a stiffener of the die package.

Example 3 includes the shield as defined in any of one or more of examples 1 or 2, wherein at least one of the first or second shield portions includes segments of EMI absorbing material spaced apart with a gap therebetween.

Example 4 includes the shield as defined in any of one or more of examples 1 to 3, wherein the first shield portion includes first segments of the first EMI absorbing material separated by a first spacing and the second shield portion includes second segments of the second EMI absorbing material separated by a second spacing different from the first spacing.

Example 5 includes the shield as defined in any of examples 1 to 4, wherein at least one of the first EMI absorbing material or the second EMI absorbing material is at least partially defined by a board-mounted EMI contact.

Example 6 includes the shield as defined in any of one or more of examples 1 to 5, wherein the first or second EMI absorbing material includes a compressible EMI gap filler material to be compressed against a component of the die package, and another of the first or second EMI absorbing material is disposed on a cold plate.

Example 7 includes the shield as defined in any of one or more of examples 1 to 6, wherein the first shield portion or the second shield portion is mounted to a substrate of the die package and another of the first or second shield portions is mounted to a cold plate.

Example 8 includes the shield as defined in any of one or more of examples 1 to 7, wherein the first shield portion or the second shield portion is segmented and another of the first or second shield portions is continuous.

Example 9 includes a die package comprising a substrate having a ground plane, a processor die supported by the substrate, and an electromagnetic interference (EMI) shield that at least partially surrounds the processor die, the shield including a first shield wall portion having a first EMI characteristic, and a second shield wall portion having a second EMI characteristic different from the first EMI characteristic, the first and second shield wall portions electrically coupled to the ground plane.

Example 10 includes the die package as defined in example 9, wherein the first and second shield wall portions include different EMI absorbing materials.

Example 11 includes the die package as defined in any of one or more of examples 9 or 10, wherein the first shield wall portion defines first, second and third lateral edges of the EMI shield, and the second shield wall portion defines a fourth lateral edge of the EMI shield.

Example 12 includes the die package as defined in any of one or more of examples 9 to 11, including a stiffener.

Example 13 includes the die package as defined in any of one or more of examples 9 to 12, wherein the second shield wall portion is at least partially composed of an EMI gap pad filler that is compressed against a memory die of the die package.

Example 14 includes the die package as defined in any of one or more of examples 9 to 13, wherein the second shield wall portion is a board-mounted component extending from the substrate.

Example 15 includes the die package as defined in any of one or more of examples 9 to 14, wherein at least one of the first shield wall portion or the second shield wall portion is segmented.

Example 16 includes the die package as defined in any of one or more of examples 9 to 15, wherein at least one of the first shield wall portion or the second shield wall portion is a printed gasket.

Example 17 includes a method of producing an electromagnetic interference (EMI) shield for a die package, the method comprising placing a first shield portion on a substrate, the first shield portion having a first EMI characteristic, and placing a second shield portion on the substrate, the second shield portion having a second EMI characteristic different from the first shield portion.

Example 18 includes the method as defined in example 17, wherein at least one of the first shield portion or the second shield portion includes a printed EMI gasket.

Example 19 includes the method as defined in any of one or more of examples 17 or 18, wherein at least one of the first shield portion or the second shield portion contacts a memory supported by the die package.

Example 20 includes the method as defined in any of one or more of examples 17 to 19, wherein at least one of the first shield portion or the second shield portion is printed as segments onto a cold plate.

Example 21 includes a computing device comprising a die package including programmable circuitry and memory, a circuit board supporting the die package, and an electromagnetic interference (EMI) shield mounted to the die package, the EMI shield including (i) a first shield portion having a first EMI absorbing material with a first characteristic, and (ii) a second shield portion having a second EMI absorbing material with a second characteristic different from the first characteristic.

From the foregoing, it will be appreciated that example systems, apparatus, articles of manufacture, and methods have been disclosed that enable space-saving and compact EMI shielding for die packages, such as SOC packages. Examples disclosed herein reduce shield complexity, reduce shield requirements, and achieve reduction in interference while enabling smaller packages and/or smaller electronic devices.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An electromagnetic interference (EMI) shield for a die package, the shield comprising:
a first shield portion defining a first section of a perimeter of the EMI shield, the first shield portion including a first EMI absorbing material with a first characteristic; and
a second shield portion defining a second section of the perimeter, the second shield portion including a second EMI absorbing material with a second characteristic different from the first characteristic, the first and second shield portions to be electrically coupled to a ground plane of the die package when the EMI shield is coupled to the die package.

2. The shield as defined in claim 1, wherein the first EMI absorbing material is a first EMI gasket and the second EMI absorbing material is a second EMI gasket, the first and second EMI gaskets to contact a stiffener of the die package.

3. The shield as defined in claim 1, wherein at least one of the first or second shield portions includes segments of EMI absorbing material spaced apart with a gap therebetween.

4. The shield as defined in claim 3, wherein the first shield portion includes first segments of the first EMI absorbing material separated by a first spacing and the second shield portion includes second segments of the second EMI absorbing material separated by a second spacing different from the first spacing.

5. The shield as defined in claim 4, wherein at least one of the first EMI absorbing material or the second EMI absorbing material is at least partially defined by a board-mounted EMI contact.

6. The shield as defined in claim 1, wherein the first or second EMI absorbing material includes a compressible EMI gap filler material to be compressed against a component of the die package, and another of the first or second EMI absorbing material is disposed on a cold plate.

7. The shield as defined in claim 1, wherein the first shield portion or the second shield portion is mounted to a substrate of the die package and another of the first or second shield portions is mounted to a cold plate.

8. The shield as defined in claim 1, wherein the first shield portion or the second shield portion is segmented and another of the first or second shield portions is continuous.

9. A die package comprising:
a substrate having a ground plane;
a processor die supported by the substrate; and
an electromagnetic interference (EMI) shield that at least partially surrounds the processor die, the shield including:
a first shield wall portion having a first EMI characteristic, and
a second shield wall portion having a second EMI characteristic different from the first EMI characteristic, the first and second shield wall portions electrically coupled to the ground plane.

10. The die package as defined in claim 9, wherein the first and second shield wall portions include different EMI absorbing materials.

11. The die package as defined in claim 9, wherein the first shield wall portion defines first, second and third lateral edges of the EMI shield, and the second shield wall portion defines a fourth lateral edge of the EMI shield.

12. The die package as defined in claim 11, including a stiffener.

13. The die package as defined in claim 9, wherein the second shield wall portion is at least partially composed of an EMI gap pad filler that is compressed against a memory die of the die package.

14. The die package as defined in claim 9, wherein the second shield wall portion is a board-mounted component extending from the substrate.

15. The die package as defined in claim 9, wherein at least one of the first shield wall portion or the second shield wall portion is segmented.

16. The die package as defined in claim 15, wherein at least one of the first shield wall portion or the second shield wall portion is a printed gasket.

17. A method of producing an electromagnetic interference (EMI) shield for a die package, the method comprising:
placing a first shield portion on a substrate, the first shield portion having a first EMI characteristic; and
placing a second shield portion on the substrate, the second shield portion having a second EMI characteristic different from the first shield portion.

18. The method as defined in claim 17, wherein at least one of the first shield portion or the second shield portion includes a printed EMI gasket.

19. The method as defined in claim 17, wherein at least one of the first shield portion or the second shield portion contacts a memory supported by the die package.

20. The method as defined in claim 17, wherein at least one of the first shield portion or the second shield portion is printed as segments onto a cold plate.

21. A computing device comprising:
a die package including programmable circuitry and memory;
a circuit board supporting the die package; and
an electromagnetic interference (EMI) shield mounted to the die package, the EMI shield including:
(i) a first shield portion having a first EMI absorbing material with a first characteristic, and
(ii) a second shield portion having a second EMI absorbing material with a second characteristic different from the first characteristic.
